(19) United States
(12) Patent Application Publication
(10) Pub. No.: US 2009/0321810 A1
(43) Pub. Date: Dec. 31, 2009

(54) NON-VOLATILE MEMORY DEVICE, MEMORY CARD AND SYSTEM

(75) Inventors: Min-Kyung RYU, Seoul (KR); Byong-sun JU, Seongnam-si (KR); Myoung-bum LEE, Seoul (KR); Seung-hyun LIM, Yongin-si (KR); Sung-hae LEE, Yongin-si (KR); Young-sun KIM, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/476,574

(22) Filed: Jun. 2, 2009

(30) Foreign Application Priority Data
Jun. 25, 2008 (KR) 10-2008-0060230

(51) Int. Cl. H01L 29/788; H01L 29/792

(52) U.S. Cl. 257/321; 257/324; 257/E29.304; 257/E29.309

(57) ABSTRACT

Provided is a non-volatile memory device including; a substrate having source/drain regions and a channel region between the source/drain regions; a tunneling insulating layer formed in the channel region of the substrate; a charge storage layer formed on the tunneling insulating layer; a blocking insulating layer formed on the charge storage layer, and comprising a silicon oxide layer and a high-k dielectric layer sequentially formed; and a control gate formed on the blocking insulating layer, wherein an equivalent oxide thickness of the silicon oxide layer is equal to or greater than that of the high-k dielectric layer.

### CROSS-REFERENCE TO RELATED APPLICATIONS

This application claims the benefit of Korean Patent Application No. 10-2008-0060230, filed on Jun. 25, 2008, the subject matter of which is hereby incorporated by reference.

### BACKGROUND

The invention relates generally to a non-volatile memory device and a method of manufacturing same. More particularly, the invention relates to a non-volatile memory device, memory card and/or a memory system incorporating same, wherein the non-volatile memory device is capable of preventing charge-loss and improving a charge storage capability.

Among semiconductor memory devices, non-volatile memory devices retain stored data even in the absence of applied power. In recent years, owing to the increased demand for compact portable electronic products, such as portable multimedia reproduction devices, digital cameras, and personal digital assistants (PDAs), research into high-capacity highly integrated non-volatile memory devices for use in compact portable electronic products has rapidly progressed. The non-volatile memory devices may be classified into programmable read-only memories (PROMs), erasable and programmable read-only memories (EPROMs), and electrically erasable and programmable read-only memories (EEPROMs). A typical example of a non-volatile memory device is a flash memory device.

The flash memory device performs an erase operation and a rewrite operation in block units. Also, since the flash memory device has high integration and good data retention characteristics, the flash memory device may function as a main memory in a system and be used in an ordinary dynamic random access memory (DRAM) interface. Furthermore, since the flash memory device may be inexpensively fabricated, the flash memory device may be used as a subsidiary storage device instead of a conventional hard disk.

A cell transistor of a conventional flash memory includes a tunneling insulating layer disposed on a semiconductor substrate, a charge storage layer, a blocking insulating layer, and a control gate that are stacked sequentially. The flash memory device performs a write operation using hot electron injection or Fowler-Nordheim tunneling (F-N tunneling), and performs an erase operation by F-N tunneling. Cell characteristics of the flash memory device depend on the thickness of the tunneling insulating layer, a contact area between the charge storage layer and the semiconductor substrate, a contact area between the charge storage layer and the control gate, or the thickness of the blocking insulating layer. The cell characteristics of the flash memory device may include program speed, erase speed, the distribution of program cells, and the distribution of erase cells. Also, other characteristics related to the reliability of cells of the flash memory device include program/erase endurance and data retention.

As memory devices become smaller, it is difficult to prevent current from leaking through insulating layers formed from silicon oxide. Thus, significant research has been done seeking a replacement for silicon dioxide such as a high dielectric material, high-k material, etc. However, when a high dielectric material is used, an undesirable charge capture phenomenon may occur due to defects in the dielectric material. This charge capture reduces the overall reliability of the constituent memory devices. Additionally, most high dielectric materials must be deposited with a thickness greater than a corresponding layer of silicon oxide in order to provide a similar dielectric constant. This increased layer thickness runs counter to ongoing efforts to increase integration of semiconductor devices.

### SUMMARY

According to an aspect of the invention, there is provided a non-volatile memory device including: a substrate having source/drain regions and a channel region between the source/drain regions; a tunneling insulating layer formed in the channel region of the substrate; a charge storage layer formed on the tunneling insulating layer; a blocking insulating layer formed on the charge storage layer, and including a silicon oxide layer and a high-k dielectric layer sequentially formed; and a control gate formed on the blocking insulating layer, wherein an equivalent oxide thickness of the silicon oxide layer is equal to or greater than that of the high-k dielectric layer.

In some embodiments of the present invention, the blocking insulating layer may be a double layer including the silicon oxide layer and the high-k dielectric layer. The blocking insulating layer may be a composite layer including at least two stack structures each including the silicon oxide layer and the high-k dielectric layer.

In some embodiments of the present invention, the silicon oxide layer may be a single layer including at least one oxide of SiO₂, carbon-doped SiO₂, fluorine-doped SiO₂, and porous SiO₂. The silicon oxide layer may be a composite layer in which respective layers includes at least one oxide of SiO₂, carbon-doped SiO₂, fluorine-doped SiO₂, and porous SiO₂.

In some embodiments of the present invention, the high-k dielectric layer may be a single layer including at least one oxide of aluminum oxide, tantalum oxide, titanium oxide, yttrium oxide, zirconium oxide, zirconium silicon oxide, hafnium oxide, hafnium silicon oxide, lanthanum oxide, lanthanum aluminum oxide, lanthanum hafnium oxide, hafnium aluminum oxide, and praseodymium oxide. The high-k dielectric layer may be a composite layer in which respective layers include at least one oxide of aluminum oxide, tantalum oxide, titanium oxide, yttrium oxide, zirconium oxide, zirconium silicon oxide, hafnium oxide, hafnium silicon oxide, lanthanum oxide, lanthanum aluminum oxide, lanthanum hafnium oxide, hafnium aluminum oxide, and praseodymium oxide.

In some embodiments of the present invention, the tunneling insulating layer may be a single or composite layer including at least one material of silicon oxide, silicon nitride, silicon oxynitride, hafnium oxide, hafnium silicon oxide, aluminum oxide, and zirconium oxide.

In some embodiments of the present invention, the charge storage layer may be a floating gate or a charge trap layer. The floating gate may include polysilicon. The charge trap layer may be a single or composite layer including at least one material of silicon oxide, silicon nitride, silicon oxynitride, hafnium oxide, zirconium oxide, tantalum oxide, titanium oxide, hafnium aluminum oxide, hafnium tantalum oxide, hafnium silicon oxide, aluminum nitride, and aluminum gallium nitride.

In some embodiments of the present invention, the control gate may be a single or composite layer including at least one of polysilicon, aluminum (Al), gold (Au), beryllium (Be), bismuth (Bi), cobalt (Co), hafnium Hf), indium (In), manganese (Mn), molybdenum (Mo), nickel (Ni), lead (Pb), palladium (Pd), plutonium (Pt), rhodium (Rh), rhenium (Re), ruthenium (Ru), tantalium (Ta), tellurium (Te), titanium (Ti), tungsten (W), zinc (Zn), zirconium (Zr), and nitrides or silicides of these.

In some embodiments of the present invention, the charge storage layer may be the floating gate, and the tunneling insulating layer may have a thickness ranging between about 20 and 80 Å, the floating gate may have a thickness ranging between about 100 and 1800 Å, and the blocking insulating layer may have a thickness ranging between about 50 and 250 Å.

In some embodiments of the present invention, the charge storage layer may be the charge trap layer, and the tunneling insulating layer may have a thickness ranging between about 20 and 80 Å, the floating gate may have a thickness ranging between about 40 and 120 Å, and the blocking insulating layer may have a thickness ranging between about 50 and 250 Å.

In some embodiments of the present invention, the substrate may include any one of silicon, silicon-on-insulator, silicon-on-sapphire, germanium, silicon-germanium, and gallium-arsenide.

According to an aspect of the invention, there is provided a memory card. The memory card includes: a non-volatile memory device including, a substrate having source/drain regions and a channel region between the source/drain regions, a tunneling insulating layer formed in the channel region of the substrate; a charge storage layer formed on the tunneling insulating layer, a blocking insulating layer formed on the charge storage layer, and including a silicon oxide layer and a high-k dielectric layer sequentially deposited, and a control gate formed on the blocking insulating layer, wherein an equivalent oxide thickness of the silicon oxide layer is equal to or greater than that of the high-k dielectric layer; and a controller for controlling the memory and transmitting/receiving data to/from the memory.

According to an aspect of the invention, there is provided a system. The system includes: a non-volatile memory device including, a substrate having source/drain regions and a channel region between the source/drain regions, a tunneling insulating layer formed in the channel region of the substrate; a charge storage layer formed on the tunneling insulating layer, a blocking insulating layer formed on the charge storage layer, and including a silicon oxide layer and a high-k dielectric layer sequentially deposited, and a control gate formed on the blocking insulating layer, wherein an equivalent oxide thickness of the silicon oxide layer is equal to or greater than that of the high-k dielectric layer; a processor for transmitting/receiving data to/from the memory via a bus; and an input/output device for transmitting/receiving data to/from the bus.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIG. 1 is a block diagram of a non-volatile memory device according to an embodiment of the invention;

FIG. 2 illustrates the layout (plan view) of a portion of a memory cell array of a non-volatile memory device according to an embodiment of the invention;

FIGS. 3A and 3B are cross-sectional views taken along lines I-I′ and II-II′ of FIG. 2, respectively;

FIG. 4 illustrates the layout (plan view) of a portion of a memory cell array of a non-volatile memory device according to an embodiment of the invention;

FIG. 5 is a cross-sectional view taken along a line V-V′ of FIG. 4;

FIG. 6 is a cross-sectional view of a non-volatile memory device according to exemplary embodiments of the invention;

FIG. 7 is a cross-sectional view of a non-volatile memory device according to exemplary embodiments of the invention;

FIG. 8 is a graph of a gate current with respect to an equivalent oxide thickness (EOT) of silicon oxide in blocking insulating layers of non-volatile memory devices according to exemplary embodiments of the invention;

FIG. 9 is a graph showing a change in threshold voltages before and after the test of non-volatile memory devices according to exemplary embodiments of the invention;

FIG. 10 is a schematic view of a memory card according to an embodiment of the invention; and

FIG. 11 is a schematic view of a system according to an embodiment of the invention.

### DESCRIPTION OF EMBODIMENTS

Embodiments of the invention will now be described in some additional detail with reference to the accompanying drawings. However, embodiments of the invention are not limited to only the illustrated embodiments. Rather, the illustrated embodiments are presented as teaching examples. In the drawings, certain layer thicknesses (or relative layer thicknesses) may be exaggerated for clarity.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of embodiments.

Unless otherwise defined, all terms (including technical and scientific terms) used herein have the same meaning as commonly understood by one of ordinary skill in the art to which embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

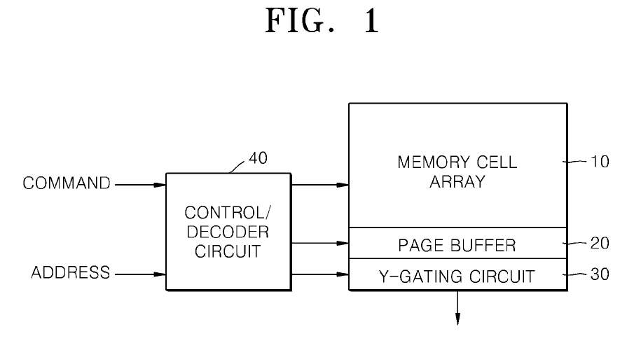

FIG. 1 is a block diagram of a non-volatile memory device according to an embodiment of the invention.

Referring to FIG. 1, the exemplary non-volatile memory device includes a memory cell array 10, a page buffer 20, a Y-gating circuit 30, and a control/decoder circuit 40.

The memory cell array 10 includes a plurality of memory blocks, and each of the plurality of memory blocks includes a plurality of non-volatile memory cells. In the illustrated embodiment, it is assumed that the non-volatile memory cells are flash memory cells. The page buffer 20 temporarily stores data to be written in the memory cell array 10, or data to be read from the memory cell array 10. The Y-gating circuitry 30 transmits data stored in the page buffer 20. The control/decoder circuitry 40 receives an externally provided command and address, outputs a control signal to write data in the memory cell array 10, or read data from the memory cell array 10, and decodes the address. The control/decoder circuitry 40 outputs a control signal for input and output of data to the page buffer 20 and provides address information to the Y-gating circuitry 30.

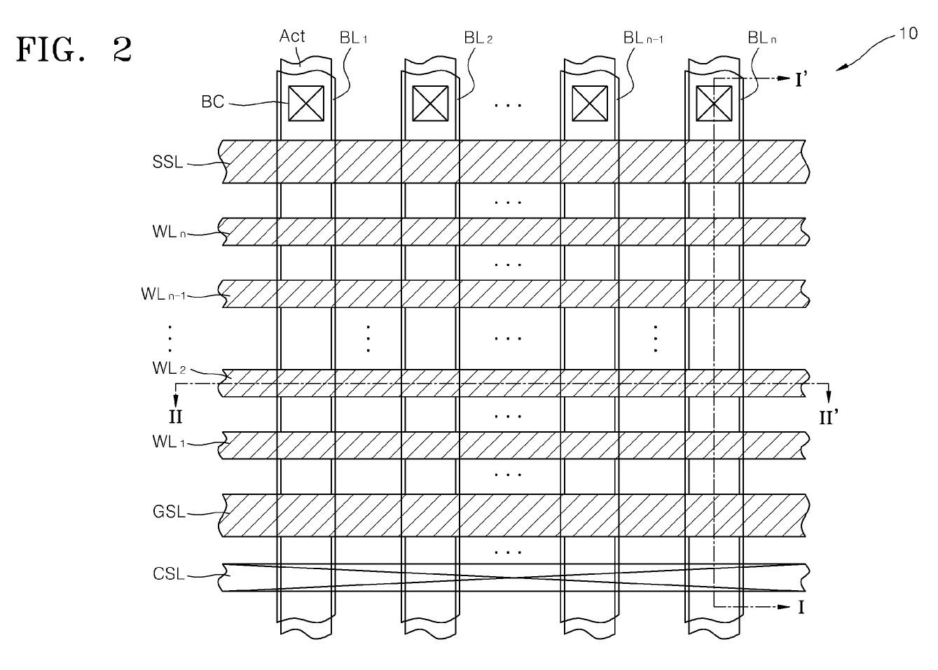

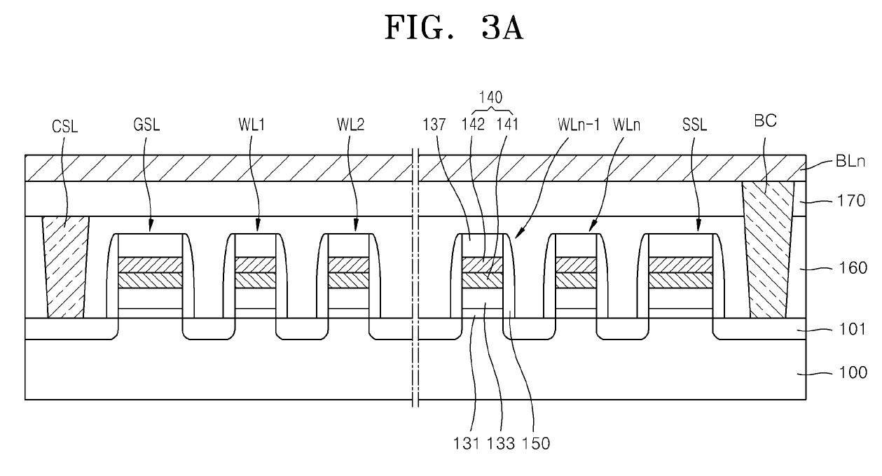

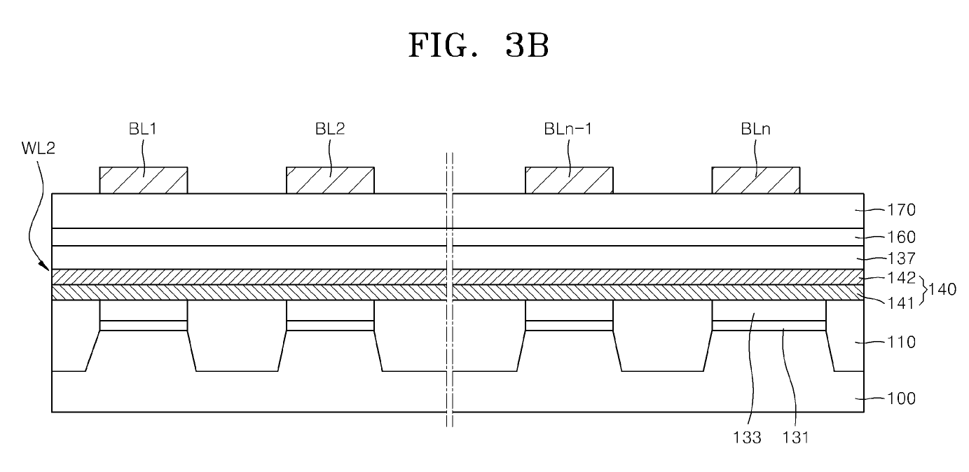

FIG. 2 illustrates the layout of a portion of a memory cell array according to an embodiment of the invention. The portion of the memory cell array shown in FIG. 2 is assumed to be a portion of the memory cell array 10 in FIG. 1. FIGS. 3A and 3B are cross-sectional views taken along lines I-I′ and II-II′ of FIG. 2, respectively.

Referring collective to FIGS. 2, 3A, and 3B, the memory cell array 10 includes a plurality of active regions (Act) that are defined by device isolation regions 110 formed in a semiconductor layer 100. The semiconductor layer 100 may include a substrate and/or an epitaxial layer, a silicon on insulator layer, and/or the like. In the illustrated embodiment, the active regions are formed in parallel lines.

A string selection line SSL and a ground selection line GSL run across and over the active regions. A plurality of word lines WL1, WL2, . . . , WLn−1, and WLn also run across and over the active regions between the string selection line SSL and the ground selection line GSL. The string selection line SSL, the ground selection line GSL, and the word lines WL1, WL2, . . . , WLn−1, and WLn are arranged in parallel with one another. Impurity regions 101 are formed in the active regions adjacent to both sides of each of the word lines WL1, WL2, . . . , WLn−1, and WLn, the string selection line SSL, and the ground selection line GSL. As a result, series connected strings of selection transistor, cell transistors, and a ground selection transistor are formed. The string selection transistor, the ground selection transistor, and the cell transistors interposed there between generally constitute a unit memory block. The impurity region 101 disposed adjacent to the string selection line SSL and opposite to the ground selection line GSL may be defined as a drain region of the string selection transistor. Also, the impurity region 101 disposed adjacent to the ground selection line GSL and opposite to the string selection line SSL may be defined as a source region of the ground selection transistor.

Each of the word lines WL1, WL2, . . . , WLn−1, and WLn in the illustrated embodiment includes a tunneling insulating layer 131, a charge storage layer 133, a blocking insulating layer 140, and a gate conductive layer 137 stacked sequentially on the semiconductor layer 100. Although not illustrated, each of the word lines WL1, WL2, . . . , WLn−1, and WLn may further include a cell barrier conductive layer and a word line conductive layer stacked sequentially on the gate conductive layer 137.

Each of the tunneling insulating layer 131 and the charge storage layer 133 is separated into portions with respect to the cell transistors disposed adjacently in the direction of the word lines WL1, WL2, . . . , WLn−1, and WLn. Top surfaces of the device isolation regions 110 may be at substantially the same level as a top surface of the charge storage layer 133. The tunneling insulating layer 131 may be formed, for example of silicon oxide. The charge storage layer 133 may be a charge trapping layer or a floating gate conductive layer. The blocking insulating layer 140 shared among the cell transistors is disposed adjacently in the direction of the word lines WL1, WL2, . . . , WLn−1, and WLn. In certain embodiment, the blocking insulating layer 140 may be a multi-layer structure. That is, the blocking insulating layer 140 may include, for example, a silicon oxide layer 141 and a high-k dielectric layer 142. The blocking insulating layer 140 will be described in some additional detail hereafter. A spacer 150 is disposed on side surfaces of the tunneling insulating layer 131, the charge storage layer 133, the blocking insulating layer 140, and the gate conductive layer 137. The spacer 150 may also be formed as a multi layer structure.

A string selection line SSL and a ground selection line GSL have the same stacked structures as word lines WL1, WL2, . . . , WLn−1, and WLn described above. In generally, widths for the string selection line SSL and the ground selection line GSL are greater than those for the word lines WL1, WL2, . . . , WLn−1, and WLn. However, such relative widths are not mandated by the present invention.

A first interlayer insulating layer 160 is provided on the word lines WL1, WL2, . . . , WLn−1, and WLn, the string selection line SSL and the ground selection line GSL. A common source line CSL is disposed through the first interlayer insulating layer 160 and connected to the source region of the ground selection line GSL. The common source line CSL is disposed parallel to the ground selection line GSL. A second interlayer insulating layer 170 is provided on the first interlayer insulating layer 160. A bit line plug BC is disposed through the second interlayer insulating layer 170 and the first interlayer insulating layer 160, and is connected to the drain region of the string selection line SSL. Bit lines BL1, BL2, . . . , BLn−1, and BLn are disposed on the second interlayer insulating layer 170 and connected to the bit line plug BC. Also, the bit lines BL1, BL2, . . . , BLn−1, and BLn run across and over the word lines WL1, WL2, . . . , WLn−1, and WLn. In the illustrated embodiment, the bit lines BL1, BL2, BLn−1, and BLn are disposed parallel to the active regions.

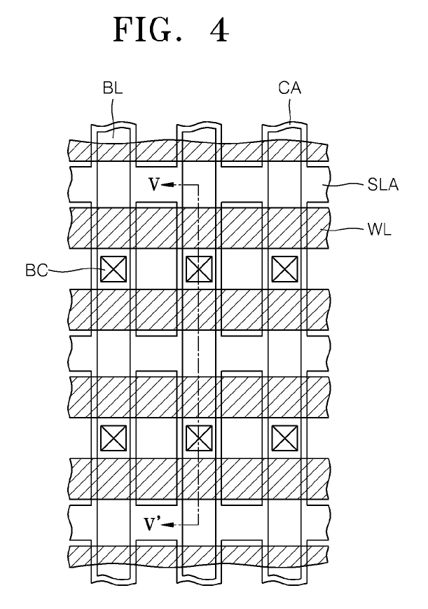

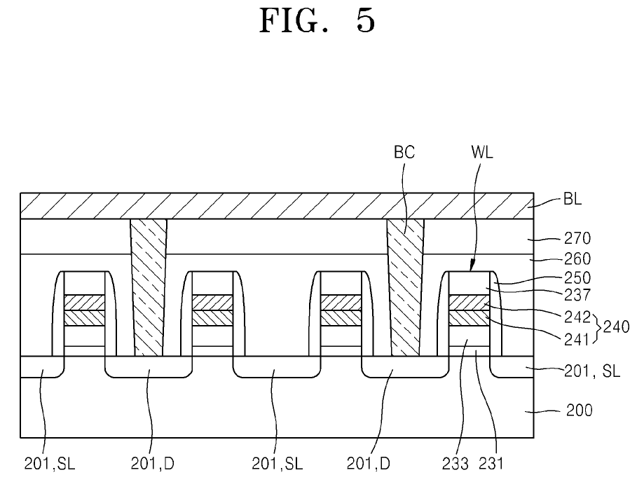

FIG. 4 illustrates the layout of a portion of the memory cell array for the nonvolatile memory device 10 of FIGS. 1 and 2 according to an embodiment of the invention. In the embodiment illustrated in FIG. 4, the memory cells forming the memory cell are assumed to be NOR flash memory cells, but the scope of the present invention is not limited to only this type of memory cell. FIG. 5 is a cross-sectional view taken along a line V-V′ of FIG. 4.

Referring to FIGS. 4 and 5, an active region is defined by a device isolation layer formed in a semiconductor layer 200. The active region includes a plurality of parallel common source line active regions SLA and a plurality of cell active regions CA disposed across the common source line active regions SLA.

A pair of word lines WL are disposed over each of the cell active regions CA and spaced apart from one another. The word lines WL are disposed adjacent to the common source line active regions SLA, respectively. Impurity regions 201 are formed in the cell active region CA and the common source line active region SLA that are exposed between the pair of word lines WL. As a result, a pair of cell transistors is defined on each of the cell active regions CA. The impurity region 201 formed in the cell active region CA is defined as a drain region D, while the impurity region 201 formed in the common source line active region SLA is defined as a common source region CS.

Each of the word lines WL includes a tunneling insulating layer 231, a charge storage layer 233, a blocking insulating layer 240, and a gate conductive layer 237 stacked sequentially on the semiconductor layer 200. Although not illustrated, each of the word lines WL may further include a barrier conductive layer and/or a word line conductive layer stacked sequentially on the gate conductive layer 237. The tunneling insulating layer 231, the charge storage layer 233, the blocking insulating layer 240, and the gate conductive layer 237 may be formed in a similar manner as the tunneling insulating layer 131, the charge storage layer 133, the blocking insulating layer 140, and the gate conductive layer 137, respectively, which are described above with reference to FIGS. 2, 3A, and 3B. Also, the blocking insulating layer 240 may have a multi-layer structure. That is, the non-volatile memory device 240 may include, for example, a silicon oxide layer 241 and a high-k dielectric layer 242. The blocking insulating layer 240 will be described in some additional detail hereafter. A spacer 250 is disposed on side surfaces of the tunneling insulating layer 231, the charge storage layer 233, the blocking insulating layer 240, and the gate conductive layer 237. The spacer 250 may also be formed as a multiple layer structure.

An interlayer insulating layer 260 is provided on the word lines WL. A bit line plug BC is disposed through the interlayer insulating layer 260 and is connected to the drain region D. Bit lines BL are disposed on the interlayer insulating layer 260 and connected to the bit line plug BC. In the illustrated embodiment, the bit lines BL across and over the word lines WL, and are disposed parallel to the cell active regions CA.

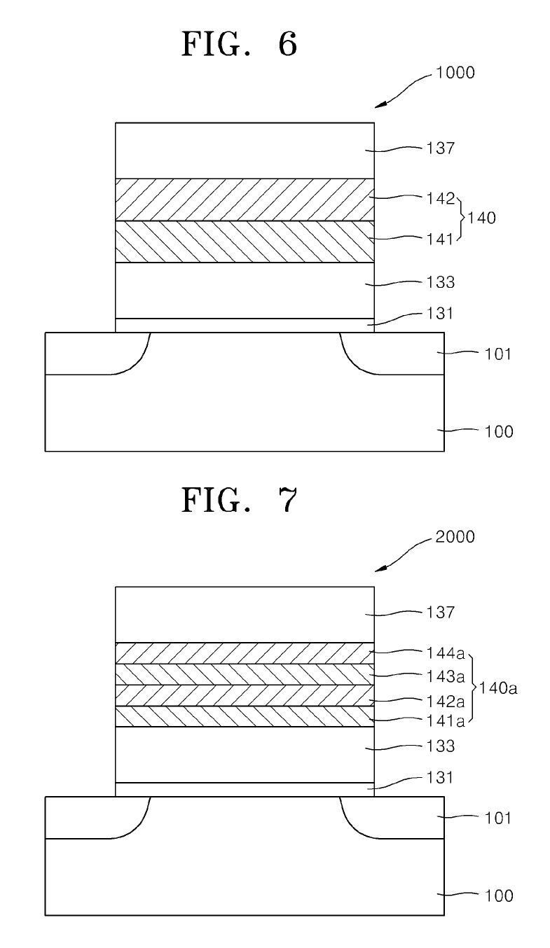

FIG. 6 is a cross-sectional view of a non-volatile memory device 1000 according to an embodiment of the invention. FIG. 7 is a cross-sectional view of a non-volatile memory device 2000 according to an embodiment of the invention.

Referring to FIGS. 6 and 7, each of the non-volatile memory devices 1000 and 2000 includes a stack structure in which a plurality of layers are formed on a substrate 100 having an active region 101 that is doped with one or more conductive impurities. The stack structure may include a tunneling insulating layer 131, a charge storage layer 133, a blocking insulating layer 140 or 140a, and a control gate 137 which are sequentially stacked in this order.

The substrate 100 may be a semiconductor substrate, and may include, for example, any one material of silicon, silicon-on-insulator, silicon-on-sapphire, germanium, silicon-germanium, and gallium-arsenide.

The impurity region 101 may be used as a source or drain (hereinafter referred to as source/drain) region and a channel region between source/drain regions. Although not illustrated, the substrate 100 may include a device isolation layer formed by a shallow trench isolation (STI) process and a well region formed by an ion implantation process.

The tunneling insulating layer 131 contacting the impurity region 101 is disposed on the substrate 100. The tunneling insulating layer 131 may be formed using a dry oxidization method or a wet oxidization method. For example, when the tunneling insulating layer 131 is formed using the wet oxidization method, a wet oxidation process is performed in a temperature range from 700 to 800° C. and then an annealing process is performed at about 900° C. in a nitrogen atmosphere for 20 to 30 minutes to form the tunneling insulating layer 131. Also, the tunneling insulating layer 131 may be a single or composite layer including at least one material of silicon oxide, silicon nitride, silicon oxynitride, hafnium oxide, hafnium silicon oxide, aluminum oxide, and zirconium oxide. (Hereafter, the phrase “at least a single layer” is used to denote either a single layer or a composite layer). However, the method of forming the tunneling insulating layer 131, and the stack structure, thickness, and material of the tunneling insulating layer 131 are just examples, and the present invention is not limited thereto.

The charge storage layer 133 is disposed on the tunneling insulating layer 131. The charge storage layer 133 may be a floating gate or a charge trap layer. When the charge storage layer 133 is the floating gate, the charge storage layer 133 may be formed by depositing polysilicon by performing chemical vapor deposition (CVD), for example, low pressure chemical vapor deposition (LPCVD) using SiH₄ gas or a gaseous mixture of Si₂H₆ and PH₃. When the charge storage layer 133 is the charge trap layer, the charge storage layer 133 may be a single or composite layer including at least one material of silicon oxide, silicon nitride, silicon oxynitride, hafnium oxide, zirconium oxide, tantalum oxide, titanium oxide, hafnium aluminum oxide, hafnium tantalum oxide, hafnium silicon oxide, aluminum nitride, and aluminum gallium nitride. However, the method of forming the charge storage layer 133 and the stack structure and material of the charge storage layer 133 are just examples, and the present invention is not limited thereto.

The blocking insulating layer 140 or 140a is disposed on the charge storage layer 133. The blocking insulating layer 140 or 140a may include a stack including a silicon oxide layer and a high-k dielectric layer. A blocking insulating layer 140 illustrated in FIG. 6 is a double layer including a silicon oxide layer 141 and a high-k dielectric layer 142. A blocking insulating layer 140a illustrated in FIG. 7 is a composite layer including at least two stack structures of silicon oxide layers and high-k dielectric layers. That is, a lower silicon oxide layer 141a, a lower high-k dielectric layer 142a, an upper silicon oxide layer 143a, and an upper high-k dielectric layer 144a may be sequentially disposed on the charge storage layer 30 in this order. In addition, a silicon oxide layer and a high-k dielectric layer may be further formed. The high-k dielectric layers 142, 142a, and 144a may be disposed on the silicon oxide layers 141, 141a, and 143a, respectively. That is, the silicon oxide layers 141 and 141a may be directly disposed on the charge storage layer 133, and the control gate 137 may be directly disposed on the high-k dielectric layers 142 and 142a.

The silicon oxide layers 141, 141a, and 143a may be formed of the same material and the same inner structure. Each of the silicon oxide layers 141, 141a, and 143a may be a single layer including at least one oxide of SiO₂, carbon-doped SiO₂, fluorine-doped SiO₂, and porous SiO₂. In addition, each of the silicon oxide layers 141, 141a, and 143a may be, for example, high temperature oxide (HTO) layers having an excellent pressure-resistant characteristic and a time dependent dielectric breakdown (TDDB) characteristic and formed by high-temperature oxidation using SiH₂Cl₂ and H₂O gas as source gases. However, the method of forming the silicon oxide layers 141, 141a, and 143a is just an example, and the present invention is not limited thereto.

Each of the high-k dielectric layers 142, 142a, and 144a may be a single layer including at least one oxide of aluminum oxide, tantalum oxide, titanium oxide, yttrium oxide, zirconium oxide, zirconium silicon oxide, hafnium oxide, hafnium silicon oxide, lanthanum oxide, lanthanum aluminum oxide, lanthanum hafnium oxide, hafnium aluminum oxide, and praseodymium oxide, or a composite layer in which respective layers include at least one oxide selected from those materials.

The high-k dielectric layers 142, 142a, and 144a may be formed by an atomic layer deposition (ALD) process or a CVD process. The ALD process for forming the high-k dielectric layers 142, 142a, and 144a will now be described in detail. For example, when each of the high-k dielectric layers 142, 142a, and 144a is a double layer including a hafnium oxide layer and an aluminum oxide layer, 1) hafnium deposition, 2) nitrogen gas purging, 3) ozone gas oxidation, 4) nitrogen gas purging, 5) aluminum deposition, 6) nitrogen gas purging, 7) ozone gas oxidation, and 8) nitrogen gas purging may be sequentially performed in this order. Specifically, a source gas of hafnium is loaded into a chamber for ALD to deposit hafnium on a wafer and then, nitrogen gas is loaded to purge any un-deposited hafnium source gas. Then, ozone gas is loaded into the chamber to oxidize the hafnium layer deposited on the wafer, thereby forming a hafnium oxide layer, and then, nitrogen gas is loaded into the chamber to purge any un-reacted ozone gas. Then, a source gas of aluminum is loaded into the chamber to deposit aluminum on the hafnium oxide layer, and then a nitrogen gas is loaded to purge any un-deposited aluminum source gas. Then, ozone gas is loaded into the chamber to oxidize the aluminum layer deposited on the wafer, thereby forming an aluminum oxide layer, and then nitrogen gas is loaded to purge any un-reacted ozone gas. The process temperature of the chamber for ALD may be 200 to 400° C., and the chamber pressure may be 10 to 100 Torr. However, the method of forming the high-k dielectric layers 142, 142a, and 144a and the material and process conditions of the high-k dielectric layers 142, 142a, and 144a are just examples, and the present invention is not limited thereto. In the ALD process, the source gases may be a metal precursor including metal that forms a high-k dielectric. An example aluminum precursor may be Al₂O₃, Al(CH₃)₃.H₂O, an example hafnium precursor may be HfO₂ or HfCl₄.H₂O, an example zirconium precursor may be ZrO₂ or ZrCl₄.H₂O, an example tantalum precursor may be TaO₂, or TaCl₅.H₂O, and an example titanium precursor may be TiO₂ or TiCl₄.H₂O. In addition, a heat treatment may be selectively performed to make the high-k dielectric layer 142, 142a, and 144a more compact and to supply insufficient oxygen. The heat treatment may be performed by a furnace process, a rapid temperature process (RTP), a rapid temperature annealing (RTA) process, or a combination of at least two processes selected from the foregoing. Also, the heat treatment may be performed in an atmosphere including ozone (O₃), argon (Ar), nitrogen (N₂) or oxygen (O₂). The heat treatment may be performed in a temperature range from 100 to 400° C. at a power of 100 W to 1000 W for 10 to 60 seconds. However, the heat treatment described above is just an example, and the present invention is not limited thereto.

Referring to FIG. 6, the equivalent oxide thickness (EOT) of the silicon oxide layer 141 may be equal to or greater than that of the high-k dielectric layer 142. Referring to FIG. 7, the EOTs of the silicon oxide layers 141a and 143a may be equal to or greater than those of the high-k dielectric layers 142a and 144a. Herein, EOT refers to a calibrated thickness of layers based on silicon oxide considering dielectric constants of respective layers. For example, if silicon nitride having a dielectric constant of 7 is deposited to a thickness of 100 Å, EOT of the silicon nitride is about 57 Å. An exemplary case in which, in FIG. 6, the silicon oxide layer 141 has a thickness of 60 Å and an aluminum oxide is deposited to a thickness of 70 Å, will now be described in detail. In this case, the EOT of the aluminum oxide is 28 Å, and the EOT of the blocking insulating layer 140 is 88 Å. As a result, a ratio of the EOT of the silicon oxide layer 141 to the EOT of the blocking insulating layer 140 is 68%.

For the embodiment illustrated in FIG. 6, the EOT of the silicon oxide layer 141 may be equal to or greater than that of the high-k dielectric layer 142. For the embodiment illustrated in FIG. 7, the EOT of the lower silicon oxide layer 141a may be equal to or greater than that of the lower high-k dielectric layer 142a, and the EOT of the upper silicon oxide layer 143a may be equal to or greater than that of the upper high-k dielectric layer 144a. Alternatively, the sum of EOTs of the lower silicon oxide layer 141a and the upper silicon oxide layer 143a may be equal to or greater than the sum of EOTs of the lower high-k dielectric layer 142a and the upper high-k dielectric layer 144a.

Table 1 shows the dielectric constants, EOT, and crystal structures of exemplary high-k materials in each of high-k dielectric layers 142, 142a, and 144a.

TABLE 1

| | Dielectric | EOT - with | |
|---|---|---|---|
| Material | Constant | reference to SiO2 | Crystal structure |
| SiO2 | 4 | 1 | Amorphous |
| Si3N4 | 7 | 0.57 | Amorphous |
| Al2O3 | 10 | 0.4 | Amorphous |
| Y2O3 | 12-14 | 0.29-0.33 | Cubical |
| ZrSixOy | 12-22 | 0.18-0.33 | — |
| HfSixOy | 15-25 | 0.16-0.27 | — |
| La2O3 | 20 | 0.2 | hexagonal, and cubical |
| ZrO2 | 22 | 0.18 | monoclinic, orthorhombic, |
| | | | and cubical |
| HfO2 | 25 | 0.16 | monoclinic, orthorhombic, |
| | | | and cubical |
| Ta2O3 | 26 | 0.15 | Orthorhombic |
| Pr2O3 | 31 | 0.13 | — |
| TiO2 | 80 | 0.05 | tetragonal, rutile, and anatase |

Referring back to FIGS. 6 and 7, the silicon oxide layer 141 may be directly formed on the charge storage layer 133 and thus, unnecessary charge-trapping that may occur in the high-k dielectric layer 142 can be prevented. Accordingly, the resulting device may be more reliably operated.

The control gate 137 is disposed on the blocking insulating layer 140 or 140a, specifically on the high-k dielectric layer 142 or upper high-k dielectric layer 144a respectively constituting the blocking insulating layers 140 and 140a. The control gate 137 may be formed using a CVD process. Also, the control gate 137 may be a single or composite layer including at least one of polysilicon, aluminum (Al), gold (Au), beryllium (Be), bismuth (Bi), cobalt (Co), hafnium (Hf), indium (In), manganese (Mn), molybdenum (Mo), nickel (Ni), lead (Pb), palladium (Pd), plutonium (Pt), rhodium (Rh), rhenium (Re), ruthenium (Ru), tantalium (Ta), tellurium (Te), titanium (Ti), tungsten (W), zinc (Zn), zirconium (Zr), and nitrides or silicides of these. However, the method of forming the control gate 137, and the stack structure and material of the control gate 137 are just examples, and the present invention is not limited thereto.

Hereinafter, exemplary dimensions of the stacked layers of the non-volatile memories 1000 and 2000 are described in detail. When the charge storage layer 133 is a floating gate, the tunneling insulating layer 131 may have a thickness of 20 Å to 80 Å, the charge storage layer 133 may have a thickness of 100 Å to 1800 Å, and the blocking insulating layer 140 or 140a may have a thickness of 50 Å to 250 Å. Also, when the charge storage layer 133 is a charge trap layer, the tunneling insulating layer 131 may have a thickness of 20 Å to 80 Å, the charge storage layer 133 may have a thickness of 40 Å to 120 Å, and the blocking insulating layer 140 or 140a may have a thickness of 50 Å to 250 Å. In addition, the control gate 137 may have a thickness of 500 Å to 2000 Å. However, these dimensions are just examples, and the present invention is not limited thereto.

Although only a flash memory device including a dielectric layer has been described in the foregoing embodiments, the present invention may be applied to other types of non-volatile memory devices including dielectric layers, such as EEPROMs and EPROMs. Also, embodiments of the invention may be applied to process methods of fabricating sub-70-nm flash memory devices using a self aligned-shallow trench isolation (SA-STI) process or a self aligned floating gate (SAFG) process.

Those skilled in the art will also be able to extend the foregoing teachings to embodiments of the invention including multi-bit flash memory cells that perform erase operations using control gate electrodes.

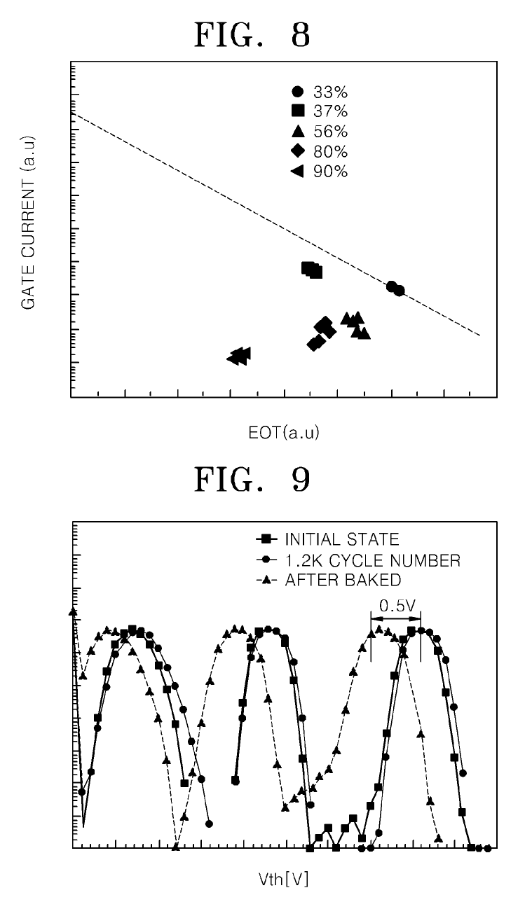

FIG. 8 is a graph of a gate current with respect to the EOT of silicon oxide in blocking insulating layers of non-volatile memory devices. In FIG. 8, a dotted plot shows a change in the gate current with respect to the EOT of a conventional blocking insulating layer.

Referring to FIG. 8, when a ratio of the EOT of the silicon oxide layer 141 or 141a to the EOT of the blocking insulating layer 140 or 140a ranges between about 33 and 37%, the gate current is similar to the conventional case. However, when a ratio of the EOT of the silicon oxide layer 141 or 141a to the EOT of the blocking insulating layer 140 or 140a increases to about 50% or more, (e.g., the example of 56%, 80%, and 90%), the gate current is reduced as compared with the conventional case. Accordingly, the leakage current prevention characteristic of the blocking insulating layer 140 or 140a according to embodiments of the invention is improved.

FIG. 9 is a graph showing a change in threshold voltages before and after the test of non-volatile memory devices according to embodiments of the invention.

Referring to FIG. 9, a change in threshold voltages when the EOT of the blocking oxide layer 141 or 141a is 76%, that is, the thickness of SiO₂ is 80 Å and the thickness of Al₂O₃ is 80 Å, is shown. In this case, a high temperature stability (HTS) characteristic is 0.5 V or lower, and thus, excellent charge retention characteristics can be obtained.

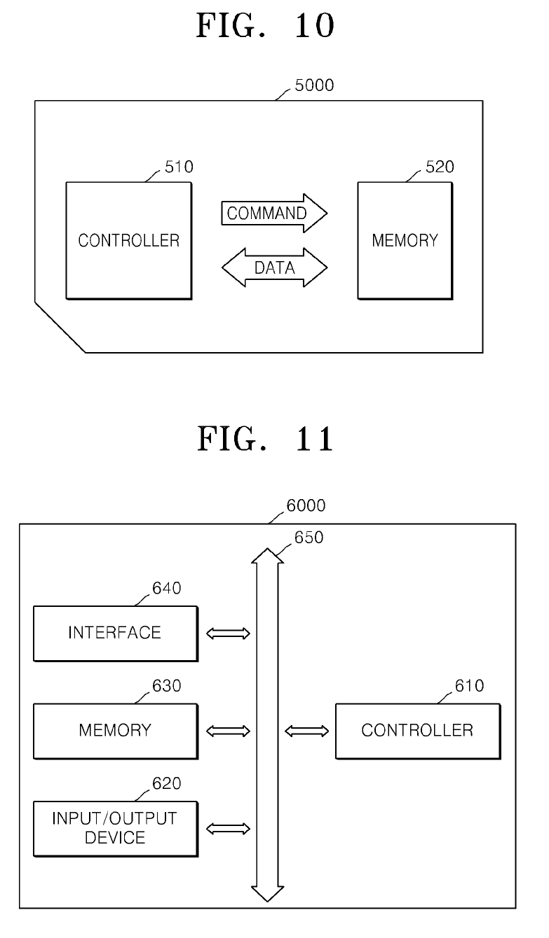

FIG. 10 is a schematic view illustrating an embodiment of a memory card 5000 according to another embodiment of the invention.

Referring to FIG. 10, a controller 510 and a memory 520 are disposed to send/receive electric signals between each other. For example, when the controller 510 gives a command to the memory 520, the memory 520 can send data. The memory 520 can include the non-volatile memory device 100 according to an embodiment of the present invention. The non-volatile memory devices according to the various embodiments of the present invention can be disposed in NAND or NOR architecture arrays in correspondence to the logic gate design. Such NAND and NOR arrays are generally well known to those of ordinary skill in the art. The memory arrays disposed in a plurality of rows and columns can have one or more memory array banks (not shown). The memory 520 can include the memory array (not shown) or the memory array bank (not shown), all of which are well known to those of ordinary skill in the art. The memory card 5000 can further include conventional members, such as a conventional row decoder (not shown), a column decoder (not shown), input/output (I/O) buffers (now shown), and/or a control resistor (not shown) in order to drive the memory array bank (not shown), all of which are well known to those of ordinary skill in the art. The memory card 5000 can be used in memory devices as a memory card, such as a memory stick card, a smart media (SM) card, a secure digital (SD) card, a mini SD card, or a multi media card (MMC).

FIG. 11 is a schematic diagram of a system 6000 including a non-volatile memory device according to an embodiment of the invention.

Referring to FIG. 11, the system 6000 may include a controller 610, an input/output device 620, a memory 630, and an interface 640. The system 6000 may be a mobile system or a system that transmits or receives data. The mobile system may be a personal digital assistant (PDA), a portable computer, a web tablet, a wireless phone, a mobile phone, a digital music player, or a memory card. The controller 610 executes a software program and controls the system 6000. The controller 610 may be a microprocessor, a digital signal processor, a microcontroller, or the like. The input/output device 630 can be used to input or output data of the system 6000. The system 6000 is connected to an external apparatus, for example, a personal computer or a network, using the input/output device 620, to send/receive data to/from the external apparatus. The input/output device 620 may be a keypad, a keyboard, or a display. The memory 630 may store codes and/or data for operating the controller 610 and/or may store data processed by the controller 610. The memory 630 may include a non-volatile memory device according to an embodiment of the present invention. The interface 640 may be a data transmission path between the system 6000 and an external apparatus. The controller 610, the input/output device 620, the memory 630, and the interface 640 may communicate with one another by a bus 650. For example, the system 6000 can be used in a mobile phone, a MP3 player, a navigation system, a portable multimedia player (PMP), a solid state disk (SSD), or a household appliance.

The foregoing is illustrative of example embodiments and is not to be construed as limiting thereof. Although example embodiments have been described, those skilled in the art will readily appreciate that many modifications are possible in example embodiments without materially departing from the novel teachings and advantages of example embodiments. Accordingly, all such modifications are intended to be included within the scope of the claims. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. A non-volatile memory device comprising:
a substrate having source/drain regions and a channel region between the source/drain regions;
a tunneling insulating layer formed in the channel region of the substrate;
a charge storage layer formed on the tunneling insulating layer;
a blocking insulating layer formed on the charge storage layer, and comprising a silicon oxide layer and a high-k dielectric layer sequentially formed; and
a control gate formed on the blocking insulating layer,
wherein an equivalent oxide thickness of the silicon oxide layer is equal to or greater than that of the high-k dielectric layer.

2. The non-volatile memory device of claim 1, wherein the blocking insulating layer is a double layer comprising the silicon oxide layer and the high-k dielectric layer.

3. The non-volatile memory device of claim 1, wherein the blocking insulating layer is a composite layer comprising at least two stack structures each comprising the silicon oxide layer and the high-k dielectric layer.

4. The non-volatile memory device of claim 1, wherein the silicon oxide layer is a single layer comprising at least one oxide of SiO₂, carbon-doped SiO₂, fluorine-doped SiO₂, and porous SiO₂.

5. The non-volatile memory device of claim 1, wherein the silicon oxide layer is a composite layer in which respective layers comprise at least one oxide selected from a group of oxides including SiO₂, carbon-doped SiO₂, fluorine-doped SiO₂, and porous SiO₂.

6. The non-volatile memory device of claim 1, wherein the high-k dielectric layer is a single layer comprising at least one oxide selected from a group of oxides including aluminum oxide, tantalum oxide, titanium oxide, yttrium oxide, zirconium oxide, zirconium silicon oxide, hafnium oxide, hafnium silicon oxide, lanthanum oxide, lanthanum aluminum oxide, lanthanum hafnium oxide, hafnium aluminum oxide, and praseodymium oxide.

7. The non-volatile memory device of claim 1, wherein the high-k dielectric layer is a composite layer in which respective layers comprise at least one oxide selected from a group of oxides including aluminum oxide, tantalum oxide, titanium oxide, yttrium oxide, zirconium oxide, zirconium silicon oxide, hafnium oxide, hafnium silicon oxide, lanthanum oxide, lanthanum aluminum oxide, lanthanum hafnium oxide, hafnium aluminum oxide, and praseodymium oxide.

8. The non-volatile memory device of claim 1, wherein the tunneling insulating layer is at least a single layer comprising at least one material selected from a group of materials including silicon oxide, silicon nitride, silicon oxynitride, hafnium oxide, hafnium silicon oxide, aluminum oxide, and zirconium oxide.

9. The non-volatile memory device of claim 1, wherein the charge storage layer is a floating gate or a charge trap layer.

10. The non-volatile memory device of claim 9, wherein the floating gate comprises polysilicon.

11. The non-volatile memory device of claim 9, wherein the charge trap layer is at least a single layer comprising at least one material selected from a group of materials including silicon oxide, silicon nitride, silicon oxynitride, hafnium oxide, zirconium oxide, tantalum oxide, titanium oxide, hafnium aluminum oxide, hafnium tantalum oxide, hafnium silicon oxide, aluminum nitride, and aluminum gallium nitride.

12. The non-volatile memory device of claim 1, wherein the control gate is at least a single layer comprising at least one material selected from a group of materials including polysilicon, aluminum (Al), gold (Au), beryllium (Be), bismuth (Bi), cobalt (Co), hafnium Hf), indium (In), manganese (Mn), molybdenum (Mo), nickel (Ni), lead (Pb), palladium (Pd), plutonium (Pt), rhodium (Rh), rhenium (Re), ruthenium (Ru), tantalium (Ta), tellurium (Te), titanium (Ti), tungsten (W), zinc (Zn), zirconium (Zr), and corresponding nitrides and silicides of each material in the group.

13. The non-volatile memory device of claim 9, wherein the charge storage layer is the floating gate,
wherein the tunneling insulating layer has a thickness ranging between about 20 and 80 Å,
wherein the floating gate has a thickness ranging between about 100 and 1800 Å,
wherein the blocking insulating layer has a thickness ranging between about 50 and 250 Å.

14. The non-volatile memory device of claim 9, wherein the charge storage layer is the charge trap layer, and
wherein the tunneling insulating layer has a thickness ranging between about 20 and 80 Å,
wherein the floating gate has a thickness ranging between about 40 and 120 Å,
wherein the blocking insulating layer has a thickness ranging between about 50 and 250 Å.

15. The non-volatile memory device of claim 1, wherein the substrate comprises at least one of silicon, silicon-on-insulator, silicon-on-sapphire, germanium, silicon-germanium, and gallium-arsenide.

16. A memory card comprising:
a memory including a non-volatile memory device; and
a controller controlling the communication of data to/from the memory, wherein the memory comprises:
a substrate having source/drain regions and a channel region between the source/drain regions;
a tunneling insulating layer formed in the channel region of the substrate;
a charge storage layer formed on the tunneling insulating layer;
a blocking insulating layer formed on the charge storage layer, and comprising a silicon oxide layer and a high-k dielectric layer sequentially formed; and
a control gate formed on the blocking insulating layer,
wherein an equivalent oxide thickness of the silicon oxide layer is equal to or greater than that of the high-k dielectric layer

17. A system comprising:
a non-volatile memory device;
a processor controlling the communication of data to/from the non-volatile memory via a bus; and
an input/output device enabling the communication of data to/from the bus,
wherein the memory comprises:
a substrate having source/drain regions and a channel region between the source/drain regions;
a tunneling insulating layer formed in the channel region of the substrate;
a charge storage layer formed on the tunneling insulating layer;
a blocking insulating layer formed on the charge storage layer, and comprising a silicon oxide layer and a high-k dielectric layer sequentially formed; and
a control gate formed on the blocking insulating layer,
wherein an equivalent oxide thickness of the silicon oxide layer is equal to or greater than that of the high-k dielectric layer.
